(19) United States
(12) Patent Application Publication
(10) Pub. No.: US 2019/0140214 A1
(43) Pub. Date: May 9, 2019

(54) Extraction Substrate And Method For Fabrication Thereof

(71) Applicant: SABIC Global Technologies B.V., Bergen op Zoom (NL)

(72) Inventors: Sang Hoon Kim, Seoul (KR); Hoo Keun Park, Seoul (KR)

(73) Assignee: SABIC Global Technologies B.V., Bergen op Zoom (NL)

(21) Appl. No.: 16/096,153

(22) PCT Filed: Apr. 27, 2017
(86) PCT No.: PCT/IB2017/052451

§ 371 Date: Oct. 24, 2018

Related U.S. Application Data
(60) Provisional application No. 62/329,463, filed on Apr. 29, 2016.

(51) Int. Cl. H01L 51/52; H01L 51/00; H01L 51/56

(52) U.S. Cl. CPC H01L 51/5268; H01L 51/0097; H01L 51/56; H01L 51/5275; H01L 2251/5369; H01L 51/004; H01L 2251/5338; H01L 2251/558; H01L 51/0035

(57) ABSTRACT

The disclosure concerns a multifunctional flexible substrate suitable for use in an organic light emitting diode element, said flexible substrate comprising: a glass layer; a first polymer film disposed on a first surface of the glass layer; and a second polymer film disposed on a second surface of the glass layer opposite the first surface.

### TECHNICAL FIELD

The disclosure concerns flexible substrates useful in organic light emitting diodes.

### BACKGROUND

An emerging trend in electronics industry is the use of flexible, thinner, lighter and cost competitive articles. In organic light-emitting diode (OLED) lighting applications, glass substrates have been used for its high performance property in WVTR (water vapor transmission rate, grams per square meter per day g/m²/day).

Generally, OLED devices have been fabricated on a glass substrate using an evaporation method. Flexible OLED devices have attracted significant attention with respect to various flexible device applications such as bendable display or wearable lighting due to its low power consumption, high response speed, high contrast ratio, and flexibility. Glass, however, is fragile and lacking in flexibility. Further, to realize design freedom in luminaire shapes, flexible, thinner, and lighter substrates are desired, although current substrate materials do not satisfy all of these properties.

These and other shortcomings are addressed by aspects of the present disclosure.

### SUMMARY

In certain aspects, the present disclosure relates to a substrate for an OLED device. The substrate may comprise a glass substrate interposed between polymer films (e.g., polycarbonate (PC) films). As such, the substrate may be embodied as a flexible substrate with high extraction effect for use with OLED devices. The substrate having the polymer films may exhibit improved flexibility compared to the conventional glass-only substrate, based at least on a reduction of brittleness afforded by the polymer films. Moreover, the polymer films may be fabricated having various shapes (textured shape, a shape having high refractive index, a shape having high thermal resistance, a shape having scattering effect with whitening, etc.). Shapes of the films and/or the overall substrate may be configured to improve the extraction efficiency from OLED devices incorporating the substrate.

The disclosure also concerns articles comprising such flexible substrates and methods of making such articles and substrates. In particular aspects, a multifunctional flexible substrate suitable for use in an organic light emitting diode element includes: a glass layer; a first polymer film disposed on a first surface of the glass layer; and a second polymer film disposed on a second surface of the glass layer opposite the first surface.

In further aspects, a method of making a multifunctional flexible substrate suitable for use in an organic light emitting diode element includes: providing a glass layer; disposing a first polymer film on a first surface of the glass layer; and disposing a second polymer film on a second surface of the glass layer opposite the first surface.

### BRIEF DESCRIPTION OF THE DRAWINGS

FIG. 1 illustrates a schematic representation of a glass substrate interposed between polymer films.

FIG. 2 illustrates a schematic representation of a glass substrate interposed between polymer films, which have periodic or random patterns. One polymer film may have periodic or random patterns on a single side (FIG. 2A) or both sides (FIG. 2B). FIGS. 2C, 2D and 2E show various possible cases for polymer film.

FIG. 3 illustrates a schematic representation of a glass substrate interposed between polymer films, which have the dispersed nanoparticles (ZrO2, ZnO, TiO2, etc.) with high refractive index.

FIG. 4 illustrates a schematic representation of a glass substrate interposed between polymer films, which have high thermal resistance and use the white particles for whitening and scattering effects.

FIG. 5 shows the schematic of an example for atomic layer deposition method applied for particles to enhance the extraction efficiency, anti-scratch property, anti-glare and hydrophobicity for water repulsion.

### DETAILED DESCRIPTION OF ILLUSTRATIVE EMBODIMENTS

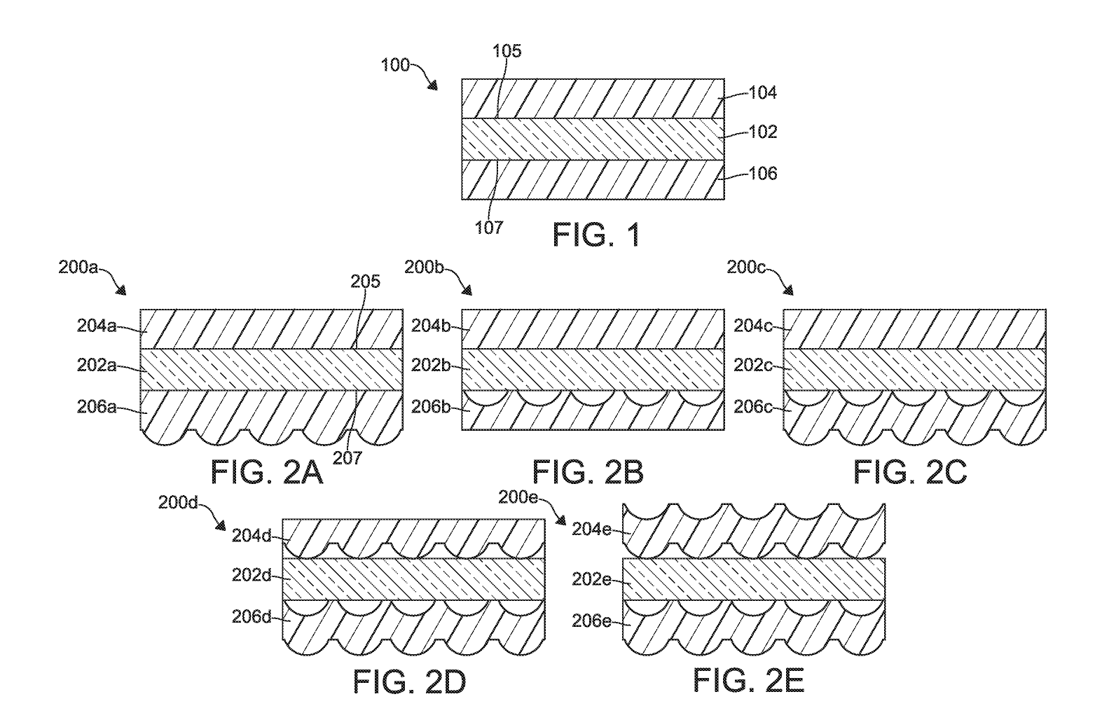

FIG. 1 illustrates a schematic representation of an example substrate 100 comprising a glass layer 102 interposed between a pair of polymer films 104, 106 (e.g., polycarbonate (PC) films). Each of the polymer films 104, 106 may be disposed on opposite surfaces 105, 107 the glass layer 102. In certain aspects, the polymer films 104, 106 may be laminated on the glass layer 102 using optically clear adhesive (OCA). Other adhesives and/or coupling techniques may be used.

In certain aspects, the substrate 100 or individual layers 102, 104, 106 of the substrate 100 may have various shapes such as a textured shape, a shape having high refractive index, a shape having high thermal resistance, a shape having scattering effect with whitening, and other shapes configured to effect a function. As an example, the substrate 100 or individuals layers 102, 104, 106 of the substrate 100 may be shaped to improve extraction efficiency from a device (e.g., OLED device) incorporating the substrate 100.

FIGS. 2A through 2E illustrate a schematic representation of an example substrate 200a-e. As shown in FIG. 2A, the substrate 200a may comprise a glass layer 202a interposed between a pair of polymer films 204a, 206a (e.g., polycarbonate (PC) films). Each of the polymer films 204a, 206a may be disposed on opposite surfaces 205, 207 the glass layer 202a. In certain aspects, the polymer films 204a may be laminated on the glass layer 202a using an optically clear adhesive (OCA). Other adhesives and/or coupling techniques may be used. As shown, one or more of the polymer films 204a may include a period or random pattern.

In certain aspects, one of the polymer films 204a-e may be configured as an extraction film for an OLED device. As such, the other of the polymer films 206a may be configured as a flat substrate for depositing an electrode and OLED layer to form an OLED device. As shown in FIG. 2A, for example, one of the polymer films 204a may include a periodic or random pattern formed on a single side, for example, using a thermal nano-imprinting method. The polymer film 204a may be heated with a hot plate at a constant temperature, which is higher than the glass transition temperature of polymer film 204a. The heated polymer film 204a may be imprinted by a periodic or random patterned mold with a constant pressure via thermal nano-imprinting method. After several minutes, the heated polymer film 204a may be cooled down to room temperature and then the pressure may be released. FIG. 2B shows similar patterns for polymer films 204b, 206b. The periodic or random patterns can be formed on the polymer film 204a after the detaching of the mold. In the same way, one of the polymer films 204c, 206c may include periodic or random patterns on both sides (e.g., opposite surfaces), as shown in FIG. 2C. In certain aspects, two patterns may be fabricated on both sides of one or more of the polymer films 204a-e, 206a-e. The two patterns may have concave and convex structures, respectively. The concave and convex structures may be fabricated according to the mold shape. As an example, FIGS. 2D and 2E illustrate various mold formations for the polymer films 204d-e, 206d-e.

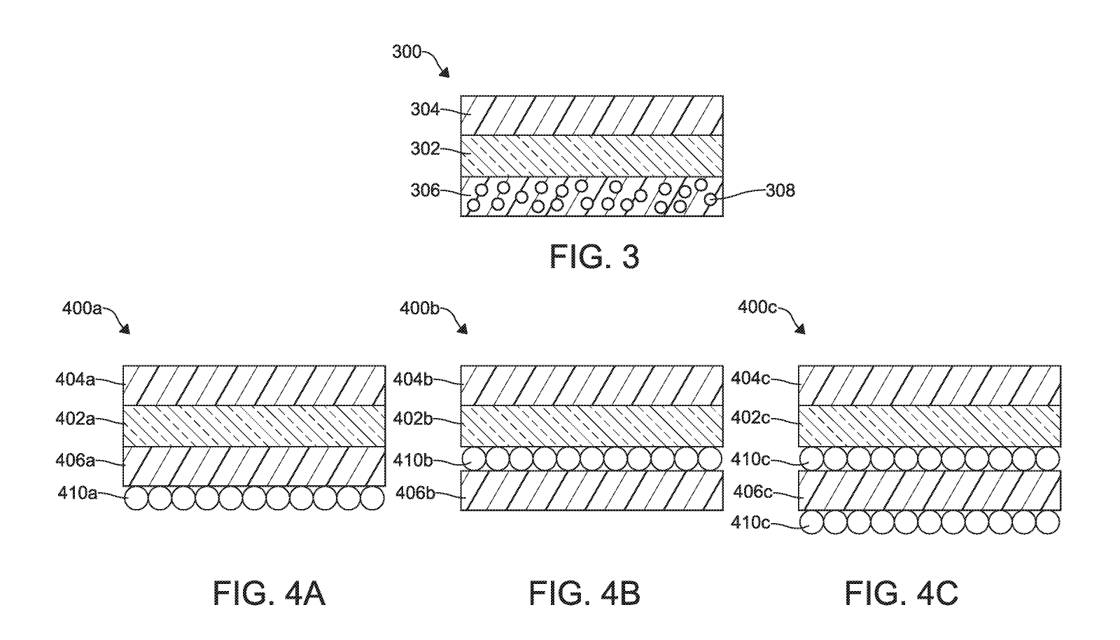

FIG. 3 illustrates a schematic representation of an example substrate 300 comprising a glass layer 302 interposed between a pair of polymer films 304, 306 (e.g., polycarbonate (PC) films). Each of the polymer films 304, 306 may be disposed on opposite surfaces 305, 307 the glass layer 302. In certain aspects, the polymer films 304 may be laminated on the glass layer 302 using an optically clear adhesive (OCA). Other adhesives and/or coupling techniques may be used. As shown, one or more of the polymer films 304 may include dispersed nanoparticles 308 (e.g., zirconium dioxide ZrO₂, zinc oxide ZnO, titanium dioxide TiO₂, etc.) having a high refractive index. In certain aspects, one or more of the polymer films 304 may include uniformly dispersed nanoparticles formed from a mixing method. The inclusion of the nanoparticles may cause the polymer film 304, 306 to exhibit a higher refractive index compared to a conventional polymer film without the nanoparticles. The refractive index of the polymer film 304 may be adjusted by changing the concentration of nanoparticles.

FIGS. 4A through 4C illustrate a schematic representation of an example substrate 400a-c comprising a glass layer 402a-c interposed between a pair of polymer films 404a-c, 406a-c (e.g., polycarbonate (PC) films). Each of the polymer films 404a-c, 406a-c may be disposed adjacent opposite surfaces 405, 407 the glass layer 402a-c. In certain aspects, the polymer films 404a-c, 406a-c may be laminated on the glass layer 402 using an optically clear adhesive (OCA). Other adhesives and/or coupling techniques may be used. One or more of the polymer films 404a-c, 406a-c may be configured to exhibit high thermal resistance. One or more of the polymer films 404 may include white particles 410a for whitening and scattering effects. For example, one or more of the polymer films 404a-c may include or be formed from a polyetherimide (e.g., ULTEM™) having high thermal resistance an may be used in the process with high temperature more easily, as compared to conventional polymer films. However, such polyetherimide films generally exhibit yellow appearance. As such, the white particles 410a-c may be used to change the yellow appearance of the polymer film 406a-c into a white appearance, as well as, to improve the extraction efficiency. As an example, the whitening layer (comprising white particles 410a-c) may be fabricated separately via an adhesive transfer (AT) method using OCA and then subsequently attached to the polymer film 404.

The glass layer 402a-c interposed between the polymer films 404 (e.g., may be configured as a flexible extraction substrate, which can exhibit multifunctional effects (e.g., higher flexibility, WVTR property, light extraction efficiency and thermal resistance), for OLED device application and future industrial applications. Particles, such as the white particles 410a-c, can be disposed in various configurations such as those illustrated in FIGS. 4A, 4B, and 4C.

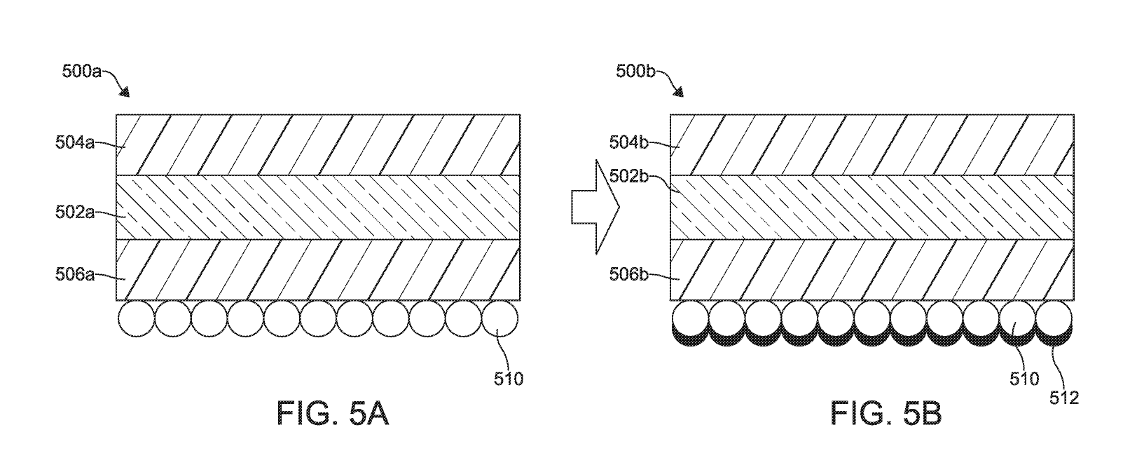

FIG. 5 illustrates a schematic representation of a process for depositing layers on the substrate. In FIG. 5A, Substrate 500a includes a glass layer 502a interposed between a pair of polymer films 504a, 506a (e.g., polycarbonate (PC) films). Each of the polymer films 504a, 506a may be disposed on opposite surfaces 505a, 507a of the glass layer 502a. In certain aspects, the polymer films 504a, 506a may be laminated on the glass layer 502a using an optically clear adhesive (OCA). Other adhesives and/or coupling techniques may be used. Particles, such as the white particles 510 forming a whitening layer, may be disposed on one or more of the polymer films, e.g., polymer film 506a. One or more of the polymer films 504a, 506a may be subjected to an atomic layer deposition method, for example, to enhance the extraction efficiency, anti-scratch property, anti-glare, and/or hydrophobicity for water repulsion to form the layered substrate 500b. Apparent as shaded layers, deposited layers 512 may be added to the substrate 500a to form the layered substrate 500b. The deposited layer 512, for example, represents layers deposited by atomic layer deposition, where thickness ranges from about 5 nanometers (nm) to about 500 nm. As a further example, materials of the layers 510 may include aluminum oxide Al₂O₃, ZrO₂, silicon dioxide SiO₂, silicon nitride oxide SiON, TiO₂, ZnO and other metal oxides.

### Substrate

The multifunctional flexible substrate may contain a base substrate that is glass. In some examples, a glass base substrate may comprise a layer having a thickness of about 20 micrometers (microns, μm) to about 100 μm (or 20 μm to 100 μm). The glass may have polymer films applied to one or more surfaces thereof The polymer films may be formed from a polymer material having high transparency. Suitable polymer materials include polycarbonate (PC), polymethylmethacrylate (PMMA), polyethylene terephthalate (PET), polyurethane (PU), polyphenylene ether (PPE), polystyrene (PS), polypropylene (PP), polyetherimide (PEI), etc.

In preparing an OLED device, the substrates as described herein may be one or more of a plurality of layers. As an example, such layers may include a scattering layer (e.g., microlens layer), a barrier layer, an electrode layer, and a phosphor layer. One or more of the plurality of layers and its associated function(s) may be incorporated into aspects of the substrate, as described herein.

### Microlens Layer

In some aspects the microlens layer serves as a light scattering layer having a base material and a plurality of scattering materials dispersed within. The refractive index of the base material and that of the light scattering material are different. Normally, the base material's refractive index ranges from 1.4 to 1.6, while the refractive index of the scattering ‘material ranges from 1.8 to above 2.0. Therefore, by adding a scattering material (e.g., a plurality of scattering particles) into base polymer, total refractive index could be increased. Typically, the light scattering layer is 5 micrometers (microns, μ) to 50 μm, or about 5 μm to about 50 μm in thickness.

The scattering materials may include air bubbles or particles of a material that are different from the base material. The scattering material may include organic particles or inorganic particles. Exemplary inorganic particles include, but are not limited to, TiO₂, niobium oxide Nb₂O₅, tungsten trioxide WO₃, bismuth(III) oxide Bi₂O₃, lanthanum oxide La₂O₃, gadolinium(III) oxide Gd₂O₃, yttrium oxide Y₂O₃, ZrO₂, ZnO, barium oxide BaO, lead(II) oxide PbO and antimony(III) oxide Sb₂O₃, phosphorous pentoxide P₂O₅, SiO₂, boron trioxide B₂O₃, germanium dioxide GeO₂, tellurium dioxide TeO₂ and combinations thereof. The amount of added scattering material ranges in some aspects from 0.1 weight percent (wt. %) to 90 wt. %, or from about 0.1 wt % to about 90 wt % relative to the amount of base material. In some aspects, the amount of added scattering material ranges from 0.5 wt. % to 80 wt. %, or from about 0.5 to about 80 wt %, or from 1 wt. % to 70 wt. % or from about 1 to about 70 wt %, or from 5 wt. % to 60 wt. 5 or from about 5 to about 60 wt %, or from 10 wt. % to 50 wt. % or from about 10 to about 50 wt %, or from 20 wt. % to 75 wt. %, or from about 20 to about 75 wt %, or any combination of the aforementioned percentages.

The base material may include in some aspects transparent organic polymers. Suitable polymers include, but are not limited to, polycarbonate (PC), poly(methyl methacrylate) (PMMA), polyethylene terephthalate (PET) and combinations thereof.

### Barrier Layer

The barrier layer(s) may include one or both of inorganic and organic materials. In one particular aspect, the barrier layer(s) includes inorganic particles in a polymer media. The layer(s) may include in some aspects a metal oxide such as oxides of aluminum, zirconium, zinc, titanium, and silicone (such as A1₂O₃, ZrO₂, ZnO, TiO₂, TiOₓ, SiO₂, and SiOₓ), a polymer including acrylate-polymer, parylene, p-xylene, or ethylene glycol, and a combination thereof. Polymer layers may be formed by molecular layer deposition (e.g., by molecular layer deposition of ethylene-glycol), plasma polymer (e.g., direct radical polymerization by plasma) or other applications known to those skilled in the art. In certain aspects the layer has a thickness of from 0.5 μm to 50 μm, or from about 0.5 μm to about 50 μm.

Electrode Layer

The electrode in some aspects is transparent. In particular aspects the electrode includes, but is not limited to, indium tin oxide ITO, tin dioxide SnO₂, ZnO, iridium zinc oxide, ZnO−Al₂O₃ (a zinc oxide doped with aluminum), ZnO₄Ga₂O₃ (a zinc oxide doped with gallium), Niobium Nb-doped TiO₂, tantalum Ta-doped TiO₂, metals such as gold Au and platinum Pt, and a combination thereof The layer in certain aspects has a thickness of 50 nm to 1 μm, or about 50 nm to about 1 μm, or 100 nm to 1 μm or about 100 nm to about 1 μm.

### Phosphor Layer

The phosphor layer may include in some aspects a phosphorescent dopant in a polymer that is transparent when the layer is formed. Different phosphorescent dopants are known in the art and can be selected based on desired color output and other properties. In particular aspects the phosphor layer may include YAG:Ce phosphors for yellow and CASN:Eu phosphors for red. YAG is yttrium aluminum garnet (Y₃Al₅O₁₂). YAG:Ce is cerium-doped YAG (YAG:Ce). CASN is CaAlSiN₃ and CASN:Eu is europium-doped CASN.

Silicones such as polydimethylsiloxane (PDMS) or an acrylic or urethane-based material may be used as binder material in certain aspects.

### Polymers

Various polymers disclosed herein are available from commercial sources. As provided herein, multifunctional flexible substrate may include one or more polymer layers or films. The polymer films may be laminated to the glass layer described herein. In some aspects, the substrate may include a first polymer film having a thickness between 10 μm and 100 μm, or about 10 μm and about 100 μm. In further aspects, the substrate may include a second polymer film having thickness between 10 μm and 100 μm, or about 10 μm and about 100 μm.

### Polycarbonate

The terms “polycarbonate” or “polycarbonates” as used herein include copolycarbonates, homopolycarbonates and (co)polyester carbonates.

The term polycarbonate can be further defined as compositions have repeating structural units of the formula (1):

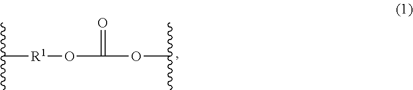

in which at least 60 percent of the total number of R¹ groups are aromatic organic radicals and the balance thereof are aliphatic, alicyclic, or aromatic radicals. In a further aspect, each R¹ is an aromatic organic radical and, more preferably, a radical of the formula (2):

—A1—Y1—A2— (2),

wherein each of A1 and A2 is a monocyclic divalent aryl radical and Y1 is a bridging radical having one or two atoms that separate A1 from A2. In various aspects, one atom separates A1 from A2. For example, radicals of this type include, but are not limited to, radicals such as —O—, —S—, —S(O)—, —S(O₂)—, —C(O)—, methylene, cyclohexyl-methylene, 2-[2.2.1]-bicycloheptylidene, ethylidene, isopropylidene, neopentylidene, cyclohexylidene, cyclopentadecylidene, cyclododecylidene, and adamantylidene. The bridging radical Y1 is preferably a hydrocarbon group or a saturated hydrocarbon group such as methylene, cyclohexylidene, or isopropylidene. Polycarbonate materials include materials disclosed and described in U.S. Pat. No. 7,786,246, which is hereby incorporated by reference in its entirety for the specific purpose of disclosing various polycarbonate compositions and methods for manufacture of the same.

In some aspects a melt polycarbonate product may be utilized. The melt polycarbonate process is based on continuous reaction of a dihydroxy compound and a carbonate source in a molten stage. The reaction can occur in a series of reactors where the combined effect of catalyst, temperature, vacuum, and agitation allows for monomer reaction and removal of reaction by-products to displace the reaction equilibrium and effect polymer chain growth. A common polycarbonate made in melt polymerization reactions is derived from bisphenol A (BPA) via reaction with diphenyl carbonate (DPC). This reaction can be catalyzed by, for example, tetra methyl ammonium hydroxide (TMAOH) or tetrabutyl phosphonium acetate (TBPA), which can be added in to a monomer mixture prior to being introduced to a first polymerization unit and sodium hydroxide (NaOH), which can be added to the first reactor or upstream of the first reactor and after a monomer mixer.

### Polymethyl Methacrylate Polymer

The term “polymethyl methacrylate” (or PMMA) is synonymous with the terms poly(methyl 2-methylpropanoate) and poly(methyl methacrylate). As used herein, the term includes homopolymers as well as copolymers of methyl methacrylate and other acrylic monomers, such as for example, ethyl acrylate, and glycidyl methacrylate in which the other acrylic monomer is present to the extent of up to 35% by weight, or up to about 35% by weight, of the composition. The polymethyl methacrylate may be stabilized with ultraviolet and thermal stabilizers and may include other additives discussed herein.

### Polyetherimides

As disclosed herein, the composition can include polyetherimides. Polyetherimides include polyetherimide copolymers. The polyetherimide can be selected from (i) polyetherimide homopolymers, e.g., polyetherimides, (ii) polyetherimide co-polymers, e.g., polyetherimidesulfones, and (iii) combinations thereof. Polyetherimides are known polymers and are sold by, e.g., SABIC Innovative Polymers under the ULTEM™, EXTEM™, and SILTEM™ brands.

In an aspect, the polyetherimides can be of formula (3):

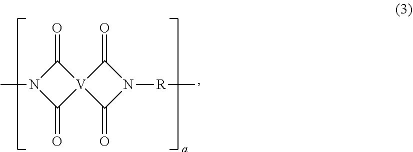

wherein a is more than 1, for example 10 to 1,000 or more, or more specifically 10 to 500. In some aspects, a can be 10-100, 10-75, 10-50 or 10-25.

The group V in formula (3) is a tetravalent linker containing an ether group (a “polyetherimide” as used herein) or a combination of an ether groups and arylenesulfone groups (a “polyetherimidesulfone”). Such linkers include but are not limited to: (a) substituted or unsubstituted, saturated, unsaturated or aromatic monocyclic and polycyclic groups having 5 to 50 carbon atoms, optionally substituted with ether groups, arylenesulfone groups, or a combination of ether groups and arylenesulfone groups; and (b) substituted or unsubstituted, linear or branched, saturated or unsaturated alkyl groups having 1 to 30 carbon atoms and optionally substituted with ether groups or a combination of ether groups, arylenesulfone groups, and arylenesulfone groups; or combinations comprising at least one of the foregoing. Suitable additional substitutions include, but are not limited to, ethers, amides, esters, and combinations comprising at least one of the foregoing.

The R group in formula (3) includes but is not limited to substituted or unsubstituted divalent organic groups such as: (a) aromatic hydrocarbon groups having 6 to 20 carbon atoms and halogenated derivatives thereof; (b) straight or branched chain alkylene groups having 2 to 20 carbon atoms; (c) cycloalkylene groups having 3 to 20 carbon atoms, or (d) divalent groups of formula (4):

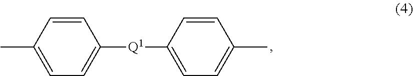

wherein Q1 includes but is not limited to a divalent moiety such as —O—, —S—, —C(O)—, —SO₂—, —SO—, —CyH₂y-(y being an integer from 1 to 5), and halogenated derivatives thereof, including perfluoroalkylene groups.

The disclosure also utilizes the polyimides disclosed in U.S. Pat. No. 8,784,719 which is incorporated herein by this reference in its entirety. In addition, the polyetherimide resin can be selected from the group consisting of a polyetherimide, for example as described in U.S. Pat. Nos. 3,875,116; 6,919,422 and 6,355,723, a silicone polyetherimide, for example as described in U.S. Pat. Nos. 4,690,997; 4,808,686, a polyetherimidesulfone resin, as described in U.S. Pat. No. 7,041,773, and combinations thereof. Each of these patents are incorporated herein by this reference in their entirety.

The polyetherimides can have a weight average molecular weight (Mw) of 5,000 to 100,000 grams per mole (g/mole) as measured by gel permeation chromatography (GPC). In some aspects the Mw can be 10,000 to 80,000. The molecular weights as used herein refer to the absolute weight average molecular weight (Mw).

### Other Polymers

Other polymers discussed herein are available from commercial sources or can be made by methods known to those skilled in the art. For example, polyethylene terephthalate (PET), polyurethane (PU), polyphenylene ether (PPE), polystyrene (PS), polypropylene (PP), and the like may be used in some aspects.

### Formation of Layers Within the Flexible Substrate

In some aspects, the disclosure concerns multifunctional flexible substrates suitable for use in an organic light emitting diode element, the flexible substrate comprising a barrier layer; a transparent electrode layer; and a microlens array layer comprising particles; wherein the barrier layer, the electrode layer, and the microlens array layer are formed into a single sheet in the absence of an adhesive layer.

Certain aspects concern a single layer multifunctional flexible substrate comprising a barrier layer; a transparent electrode layer; at least one microlens array layer comprising particles; at least one refractive index matching layer; and a phosphor layer. In some constructs, the barrier layer, the electrode layer, and the microlens array layer are formed into a single sheet in the absence of an adhesive layer. In some constructs, no adhesive is used in forming the multilayers into a single sheet.

Layers may be formed by use of one or more of ink jet printing, application of a polymer solution or slurry, roll to roll printing, vacuum vapor deposition operations or other techniques known to those skilled in the art. Additionally, an aerosol-deposition process can be used for phosphor layer coating. A microlens array film can be made by, e.g., slot die coating and extrusion methods.

In some aspects, certain layers may be laminated. The disclosure contemplates all combinations of laminated and non-laminated assemblies of each layer into a single sheet.

### Aspects

The present disclosure comprises at least the following aspects.

Aspect 1. A multifunctional flexible substrate suitable for use in an organic light emitting diode element, said flexible substrate comprising: a glass layer; a first polymer film disposed on a first surface of the glass layer; and a second polymer film disposed on a second surface of the glass layer opposite the first surface.

Aspect 2. A multifunctional flexible substrate suitable for use in an organic light emitting diode element, said flexible substrate consisting essentially of: a glass layer; a first polymer film disposed on a first surface of the glass layer; and a second polymer film disposed on a second surface of the glass layer opposite the first surface.

Aspect 3. A multifunctional flexible substrate suitable for use in an organic light emitting diode element, said flexible substrate consisting of: a glass layer; a first polymer film disposed on a first surface of the glass layer; and a second polymer film disposed on a second surface of the glass layer opposite the first surface.

Aspect 4. The multifunctional flexible substrate of any of aspects 1-3, wherein the glass layer has a thickness of between about 20 microns to about 100 microns.

Aspect 5. The multifunctional flexible substrate of any one of aspects 1-4, wherein the first polymer film has a thickness of between about 10 microns to about 100 microns.

Aspect 6. The multifunctional flexible substrate of any one of aspects 1-5, wherein the second polymer film has a thickness of between about 10 microns to about 100 microns.

Aspect 7. The multifunctional flexible substrate of any one of aspects 1-6, wherein one or more of the first polymer film and the second polymer film are laminated to the glass layer.

Aspect 8. The multifunctional flexible substrate of any one of aspects 1-7, wherein one or more of the first polymer film and the second polymer film comprises a structural pattern formed therein.

Aspect 9. The multifunctional flexible substrate of aspect 8, wherein the structural pattern comprises semi-spherical concave shapes or semi-spherical convex shapes, or both.

Aspect 10. The multifunctional flexible substrate of aspect 8, wherein the structural pattern comprises a periodic or random pattern of shaped structures.

Aspect 11. The multifunctional flexible substrate of any one of aspects 1-10, wherein one or more of the first polymer film and the second polymer film comprises dispersed nanoparticles.

Aspect 12. The multifunctional flexible substrate of aspect 11, wherein the dispersed nanoparticles comprise ZrO₂, ZnO, TiO₂, Al₂O₃ or a combination thereof

Aspect 13. The multifunctional flexible substrate of any one of aspects 1-12, wherein one or more of the first polymer film and the second polymer film comprises whitening particles.

Aspect 14. The multifunctional flexible substrate of aspect 13, wherein the whitening particles comprise ZrO₂, ZrO, ZnO, TiO₂, Al₂O₃ or a combination thereof.

Aspect 15. The multifunctional flexible substrate of any one of aspects 1-14, wherein one or more of the first polymer film and the second polymer film comprises polycarbonate (PC), polymethylmethacrylate (PMMA), polyethylene terephthalate (PET), polyurethane (PU), polyphenylene ether (PPE), polystyrene (PS), polypropylene (PP), polyetherimide (PEI), or a combination thereof

Aspect 16. The multifunctional flexible substrate of any one of aspects 1-15, further comprising a functional layer applied using atomic layer deposition.

Aspect 17. A method of making a multifunctional flexible substrate suitable for use in an organic light emitting diode element, the method comprising: providing a glass layer; disposing a first polymer film on a first surface of the glass layer; and disposing a second polymer film on a second surface of the glass layer opposite the first surface.

Aspect 18. The method of aspect 17, wherein the glass layer has a thickness of between about 20 microns to about 100 microns.

Aspect 19. The method of any one of aspects 17-18, wherein the first polymer film has a thickness of between about 10 microns to about 100 microns.

Aspect 20. The method of any one of aspects 17-19, wherein the second polymer film has a thickness of between about 10 microns to about 100 microns.

Aspect 21. The method of any one of aspects 17-20, wherein one or more of the first polymer film and the second polymer film are laminated to the glass layer.

Aspect 22. The method of any one of aspects 17-21, wherein one or more of the first polymer film and the second polymer film comprises a structural pattern formed therein.

### Definitions

It is to be understood that the terminology used herein is for the purpose of describing particular aspects only and is not intended to be limiting. As used in the specification and in the claims, the term “comprising” can include the aspects “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. In some aspects, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

The terms “refractive index” or “index of refraction” as used herein refer to a dimensionless number that is a measure of the speed of light in that substance or medium. It is typically expressed as a ratio of the speed of light in vacuum relative to that in the considered substance or medium. This can be written mathematically as:

n=speed of light in a vacuum/speed of light in medium.

The term “adhesive” as used herein refers to a sticky, gluey or tacky substance capable of adhering two films together. In preferred aspects, the adhesive is transparent. In the adhesive, desiccant material can be added for improving WVTR property. And UV or thermal energy may be necessary for curing adhesive layer.

Unless otherwise stated to the contrary herein, all test standards are the most recent standard in effect at the time of filing this application.

1. A multifunctional flexible substrate suitable for use in an organic light emitting diode element, the multifunctional flexible substrate comprising:
a glass layer;
a first polymer film disposed on a first surface of the glass layer; and
a second polymer film disposed on a second surface of the glass layer opposite the first surface.

2. The multifunctional flexible substrate of claim 1, wherein the glass layer has a thickness of between about 20 microns to about 100 microns.

3. The multifunctional flexible substrate of claim 1, wherein the first polymer film has a thickness of between about 10 microns to about 100 microns.

4. The multifunctional flexible substrate of claim 1, wherein the second polymer film has a thickness of between about 10 microns to about 100 microns.

5. The multifunctional flexible substrate of claim 1, wherein one or more of the first polymer film and the second polymer film are laminated to the glass layer.

6. The multifunctional flexible substrate of claim 1, wherein one or more of the first polymer film and the second polymer film comprises a structural pattern formed therein.

7. The multifunctional flexible substrate of claim 6, wherein the structural pattern comprises semi-spherical concave shapes or semi-spherical convex shapes, or both.

8. The multifunctional flexible substrate of claim 6, wherein the structural pattern comprises a periodic or random pattern of shaped structures.

9. The multifunctional flexible substrate of claim 1, wherein one or more of the first polymer film and the second polymer film comprises dispersed nanoparticles.

10. The multifunctional flexible substrate of claim 9, wherein the dispersed nanoparticles comprise ZrO₂, ZnO, TiO₂, Al₂O₃ or a combination thereof

11. The multifunctional flexible substrate of claim 1, wherein one or more of the first polymer film and the second polymer film comprises whitening particles.

12. The multifunctional flexible substrate of claim 11, wherein the whitening particles comprise ZrO₂, ZrO, ZnO, TiO₂, Al₂O₃ or a combination thereof.

13. The multifunctional flexible substrate of claim 1, wherein one or more of the first polymer film and the second polymer film comprises polycarbonate (PC), polymethylmethacrylate (PMMA), polyethylene terephthalate (PET), polyurethane (PU), polyphenylene ether (PPE), polystyrene (PS), polypropylene (PP), polyetherimide (PEI), or a combination thereof

14. The multifunctional flexible substrate of claim 1, further comprising a functional layer applied using atomic layer deposition.

15. A method of making a multifunctional flexible substrate suitable for use in an organic light emitting diode element, the method comprising:
providing a glass layer;
disposing a first polymer film on a first surface of the glass layer; and
disposing a second polymer film on a second surface of the glass layer opposite the first surface.

16. The method of claim 15, wherein the glass layer has a thickness of between about 20 microns to about 100 microns.

17. The method of claim 15, wherein the first polymer film has a thickness of between about 10 microns to about 100 microns.

18. The method of claim 15, wherein the second polymer film has a thickness of between about 10 microns to about 100 microns.

19. The method of claim 15, wherein one or more of the first polymer film and the second polymer film are laminated to the glass layer.

20. The method of claim 15, wherein one or more of the first polymer film and the second polymer film comprises a structural pattern formed therein.
